(19) United States
(12) Patent Application Publication
(10) Pub. No.: US 2003/0174005 A1
(43) Pub. Date: Sep. 18, 2003

(54) CMOS DIGITAL PULSE WIDTH MODULATION CONTROLLER

(76) Inventors: Paul W. Latham II, Lee, NH (US); Shawn Laliberte, Newton, NH (US); Chuck Wong, Union City, CA (US)

Correspondence Address: TYCO ELECTRONICS CORPORATION, MAIL STOP R20/2B, 307 CONSTITUTION DRIVE, MENLO PARK, CA, 94025, US

(21) Appl. No.: 10/099,703

(22) Filed: Mar. 14, 2002

(51) Int. Cl. H03K 3/017

(52) U.S. Cl. 327/172

(57) ABSTRACT

A CMOS digital PWM controller chip includes a clock generator for directly generating a sampling clock at a frequency higher than a control pulse rate without requiring a phase locked loop, an oversampling analog-to-digital converter clocked by the sampling clock for converting error signals into filtered digital values, an output for controlling duty cycle of an electrical device in accordance with width-modulated digital control pulses supplied at the control pulse rate, and, digital control logic for generating the width-modulated digital control pulses in relation to the digital values. The digital control logic may include a linear feedback shift register to pseudo-randomize the digital control pulses to reduce electromagnetic interference.

### CROSS-REFERENCE TO RELATED APPLICATIONS

The present invention is related to commonly assigned, copending U.S. patent application Ser. No. ______, filed on the same date as this application and entitled: “Three-Terminal, Low Voltage Pulse Width Modulation Controller IC” (Docket No. MP 1728-US1), the disclosure thereof being incorporated herein by reference.

### BACKGROUND OF THE INVENTION

1. Field of the Invention

The present invention relates to pulse width modulation (PWM) controllers. More particularly, the present invention relates to a digital logic based pulse width modulation (PWM) controller realized as a single complementary metal oxide semiconductor (CMOS) integrated circuit (IC) chip.

2. Introduction to the Invention

It is very desirable to minimize the cost, size and power dissipation of a low-cost off-line switching power supply for low power applications, such as recharging cells and batteries used in portable consumer appliances, such as entertainment units, personal digital assistants, and cell phones, for example. One method to achieve these desirable goals is to use one or several integrated circuit controller chips providing PWM control.

A PWM switched power supply requires a variable pulse width that is controlled by an error signal derived by comparing actual output voltage to a precise reference voltage. The pulse width of the switching interval must also be constrained to be within a minimum and maximum duration. These constraints are imposed for correct PWM power supply or motor driver operation. In a typical single-chip PWM controller IC derivation of a controlled pulse width is typically achieved by employing ramp generators, comparators, and monostable multivibrators (one-shots). These circuit elements typically require precision analog circuits with moderate to high speed, and consequently do not scale well with a high-speed logic process, such as complementary metal oxide silicon (CMOS). To take advantage of high speed, sub-micron CMOS processes now available a different approach is needed. In the new approach, digital logic circuit elements are used to replace and supersede the older analog circuit methods. Counters, magnitude comparators, state machines, and processors are used to replace the old analog elements of ramp generators, comparators and one-shots. While this conversion is desirable, the particular combination of digital logic circuit elements to achieve an effective, low cost, low power digital PWM controller solution using CMOS is not particularly obvious from the prior art approaches due to the requirement of high speed clocks and analog to digital converters with a low power.

PWM controllers are typically designed to regulate the output voltage of a switching power supply. For the best accuracy, it is desirable to control the average output voltage, rather than instantaneous voltage. Therefore, it would be desirable to filter out the output ripple. One method is to employ an ADC with intrinsic filtering. One such ADC is a delta-sigma ADC that employs oversampling and decimation to filter the ripple. However, in order to employ successfully a delta-sigma ADC, a high frequency, oversampling clock is needed.

In an integrated circuit (IC) high speed logic, comparators, amplifiers, etc., typically have both power supply and temperature sensitivity. Oscillators comprise an unstable feedback loop with one or more of these sensitive components in the loop combined with less sensitive passive components. The passive components are not as supply and temperature sensitive as the active components. However, at higher frequencies, these active circuits have a larger percentage of the delay of the loop delay. Thus, at higher frequencies, the sensitivity to supply and temperature variations remains. The classic solution to this problem is to design a power supply and temperature insensitive low frequency oscillator and up-convert the frequency using phase locked loop (PLL) techniques. This solution works well, but it is complex, relatively expensive to build, and consumes a lot of power.

Switching power supplies are known to emit electromagnetic interference (EMI) or radio frequency interference (RFI) at frequencies centered at harmonics of the switching frequency. Consequently, governmental regulators have adopted rules limiting the level of EMI that can be emitted from a switching power supply unit. The specification for conducted EMI has different specification bands. To lower the signal spectrum peaks, frequency dither has been used. Frequency dither lowers the requirements of the filtering techniques required to meet government regulations. The lower filter requirements lower the cost of the PWM-based power supply. Frequency dither is typically carried out by adding a jitter signal to the PWM clock oscillator feedback loop. For typical values of jitter employed in the prior art approaches, the switching harmonic peaks are only slightly reduced. Therefore, it would be desirable if jitter could be more accurately controlled, thereby enabling jitter to be increased and the harmonic peaks across the spectrum of EMI to be reduced even further. While the need for more precisely controlled jitter is known, the solution is not immediately apparent from prior approaches.

### BRIEF SUMMARY OF THE INVENTION

A general object of the present invention is to provide a low cost digital logic based PWM controller realized as a single CMOS IC chip in a manner overcoming limitations and drawbacks of the prior art.

Another object of the present invention is to provide a fully integrated on-chip reference oscillator for directly generating a frequency-stabilized high frequency reference clock operating at a reference clock frequency preferably in a range from 1-150 MHz without complex phase lock loop circuitry and without any external frequency-stabilizing circuit elements.

Another object of the present invention is to provide an analog-to-digital converter for a CMOS digital PWM controller chip comprising an oversampling delta-sigma modulator and a PWM-synchronized decimation filter, thereby providing very high rejection of the output ripple and all its significant harmonics.

Another object of the present invention is to provide a digital logic controller circuit for a CMOS digital PWM controller chip in a manner overcoming limitations and drawbacks of the prior art.

Another object of the present invention is to provide a CMOS digital PWM controller having digitally generated jitter modulation in order to reduce EMI otherwise emanating from a power source being controlled by the controller, in a manner overcoming limitations and drawbacks of the prior art. A related object is to incorporate controlled pseudo-random jitter modulation into the PWM control pulse repetition rate by employing a linear feedback shift register as part of a pseudo-random PWM control period generator within a digital logic PWM controller.

A further object of the present invention is to provide a digital PWM controller that may be implemented as an integrated circuit employing a low voltage CMOS fabrication process.

The foregoing and related objects and features of the present invention are realized by a digital PWM controller embodied as a small, unitary monolithic CMOS digital IC chip having, e.g., an area of about 2.26 mm² (3500 mils²) in an 0.8 micron CMOS array. In one circuit configuration the IC chip may be packaged and connected as a self-contained three terminal device. In another circuit configuration, the same IC chip may be packaged and connected as a self-contained four-or-more terminal device.

The CMOS digital IC chip includes a first input for receiving a first feedback control value related to an output parameter of a power circuit (such as a switching power supply or motor controller) which is controlled by the digital PWM controller. The IC chip includes a digital output switch, such as a field effect transistor (FET), for providing digital width-modulated control pulses at a control pulse rate to control the power circuit. The switch may have power to drive low voltage loads directly or may drive external high voltage, higher power devices. The digital control pulses are width-modulated between a minimum pulse width and a maximum pulse width in relation to the feedback control value. A digital reference clock generator is fully contained within the IC chip and without any external frequency-determining elements, such as capacitors, crystals, resonators, or the like, and it generates directly a reference clock at a reference clock rate much higher than the control pulse rate of the PWM controller. For example, if the PWM control pulse rate averages about 130 kHz with frequency dither, the reference clock preferably operates at approximately 8.3 MHz, and thereby provides a clock effectively enabling oversampling of an output feedback control signal. Accordingly, the IC chip includes at least one oversampling analog-to-digital converter, which is used for sampling at the reference clock rate the output feedback control value at the input and for putting out digital words representing average feedback control values at the control pulse rate. The IC chip further includes a digital control logic state machine that is clocked at the reference clock rate. The logic state machine generates at least a minimum PWM control pulse interval, a maximum PWM control pulse interval, and a data acquisition interval. Accordingly, the logic state machine synchronously controls the analog-to-digital converter at the control pulse rate and generates and applies the digital width-modulated control pulses to the on-chip, low voltage, current-carrying FET digital output switch for controlling the power circuit. Most preferably, the control logic state machine includes a digital pseudo-random period generator, most preferably including a linear feedback shift register, for generating controlled large frequency dither of the control pulse repetition rate, thereby to spread control pulse harmonics across a radio frequency spectrum and reduce EMI at any particular frequency within the spectrum.

An additional advantage of the high speed logic approach as compared to traditional analog techniques is that all timings are directly related to the master internal clock. Thus, any adjustment to the master clock changes all important time specifications together in a ratiometric fashion. It improves testability, integrated circuit process insensitivity, and frequency scaling. The latter allows for a much larger application range for the clock and the clocked device and at little or no extra cost.

These and other objects, advantages, aspects and features of the present invention will be more fully understood and appreciated upon consideration of the detailed description of preferred embodiments presented in conjunction with the following drawings.

### BRIEF DESCRIPTION OF THE DRAWINGS

The invention is illustrated by the drawings in which FIG. 1 is a schematic circuit diagram of an off-line switching power supply for small power applications including a low-voltage CMOS digital PWM controller IC configured in a three-terminal package in accordance with principles of the present invention.

FIG. 2 is a schematic circuit diagram of an off-line switching power supply similar to the FIG. 1 supply and using an opto-isolator to impose a separately-sensed feedback control signal upon a voltage supply for the PWM controller as used in FIG. 1.

FIG. 3 is a logic block and circuit diagram of the low-voltage CMOS digital PWM controller IC used in the FIGS. 1 and 2 switching power supplies.

FIG. 4A is a logic block diagram of a first part of the state control logic circuit shown within the PWM controller IC in the FIG. 3 block diagram.

FIG. 4B is a logic block diagram of a remaining part of the state control logic circuit of the primary side PWM controller IC of FIG. 3.

FIG. 5 is a logic block and schematic circuit diagram of a high-frequency-stabilized low power clock oscillator preferably used within the primary side PWM controller IC in the FIG. 3 block and circuit diagram.

FIG. 6 is a logic block and schematic circuit diagram of a synchronous delta-sigma analog-to-digital converter preferably used within the primary side PWM controller IC in the FIG. 3 block and circuit diagram.

FIG. 7 is an amplitude versus time base graph of step-down transformer switching current of the FIG. 1 off-line power supply conventionally operating without any frequency dither of the PWM control interval.

FIG. 8 is an amplitude versus time base graph of step-down transformer switching current of the FIG. 1 off-line power supply operating with digital frequency dither of the control interval in accordance with principles of the present invention.

FIG. 9A is an amplitude versus frequency domain graph showing operation of the FIG. 4 PWM controller with zero percent dither.

FIG. 9B is an amplitude versus frequency domain graph showing operation of the FIG. 4 PWM controller with 10.7 percent dither.

FIG. 9C is an amplitude versus frequency domain graph showing operation of the FIG. 4 PWM controller with 47.7 percent dither.

FIG. 9D is an amplitude versus frequency domain graph showing operation of the FIG. 4 PWM controller with 96.9 percent dither.

### DETAILED DESCRIPTION OF THE INVENTION

As shown in the FIG. 1 diagram of an off-line switching power supply 100, a single IC 10 having three terminals can provide PWM control at the primary side of the power supply, based upon feedback received from a secondary side bias winding 113.

As used in the example of FIG. 1, the off-line switching power supply 100 receives energy from the commercial AC power grid via a suitable connection or connector arrangement. A fuse 102 protects the power supply 100 from fault conditions. A diode bridge 104 full-wave rectifies the incoming AC power into pulsating DC, and a filter capacitor 106 lowers the AC ripple. The resultant DC voltage is applied between ground and an energy-storing primary winding 110 of e.g. a step-down transformer 109. While a step-down flyback converter is shown in the example of FIG. 1, the power supply could provide a step-up transformer, a SEPIC (Single Ended Primary Inductance Converter), a boost converter, or inverting converter, or buck converter. These are all well known in prior art PWM power supplies. The transformer 109 also includes a secondary winding 112 feeding a diode rectifier 114, a storage capacitor 116, an output filter inductor 118, and an output filter capacitor 120. Conventionally, a secondary side ground or return terminal is not connected to the off-line primary ground. The secondary-side output line may include a current sense resistor 122 enabling sensing magnitude of output current being supplied to a load. An error voltage derived from sensed load current would be combined with an error voltage derived from sensed voltage, and a composite error voltage would be fed back in a known manner to control operation of the primary side PWM controller 10.

A high voltage MOS switching transistor 124, which in this example is external to the PWM controller chip 10 to enable high current delivery by the switching power supply 100, alternately passes and blocks current flow through the primary winding 110 of the switching transformer at a predetermined relatively high frequency, such as about 130 kHz. The high voltage transistor 124 is only needed in high voltage applications; in lower voltage applications, the external high voltage transistor maybe omitted. The switched energy is stored in the primary winding 110 and core of the transformer 109 and is passed by mutual induction to secondary winding 112 in conventional fashion. A snubber circuit 128 connected across primary winding 110 protects switching transistor 124 against reverse breakdown overvoltage spikes otherwise induced in primary winding 110. The duty cycle of the transistor 124 is pulse-width-modulated in order to regulate precisely the operation of the power supply 100 in delivering electrical energy at regulated output voltage and current to a load attached to the secondary side.

In accordance with an aspect of the present invention, a low-voltage CMOS PWM controller 10 may be used in a three-terminal configuration formed by a low cost through-hole package, such as TO-92. In this configuration of PWM controller 10, the high voltage switching transistor 124 is connected and operated in a common-gate, source-switched topology within the power supply 100. In this topology, the source voltage of transistor 124 is switched between a voltage just less than the gate electrode voltage of FET 124 and ground by operation of the PWM controller 10, enabling use of the low voltage PWM controller IC 10. Gate bias voltage for the high voltage switching transistor 124 is established at a nominal low voltage above primary side ground, such as 125 volts positive, by e.g. a zener diode 125. Voltage to bias the zener diode 125 into reverse (regulating) conduction is obtained from the rectified high voltage DC via e.g. a resistance network of series resistors 129 and 131. The gate of transistor 124 may be decoupled from the zener diode 125 by a resistor 127 in the FIG. 1 example, and a capacitor 126 further smoothes the DC gate voltage established by reverse breakdown characteristics of zener diode 125.

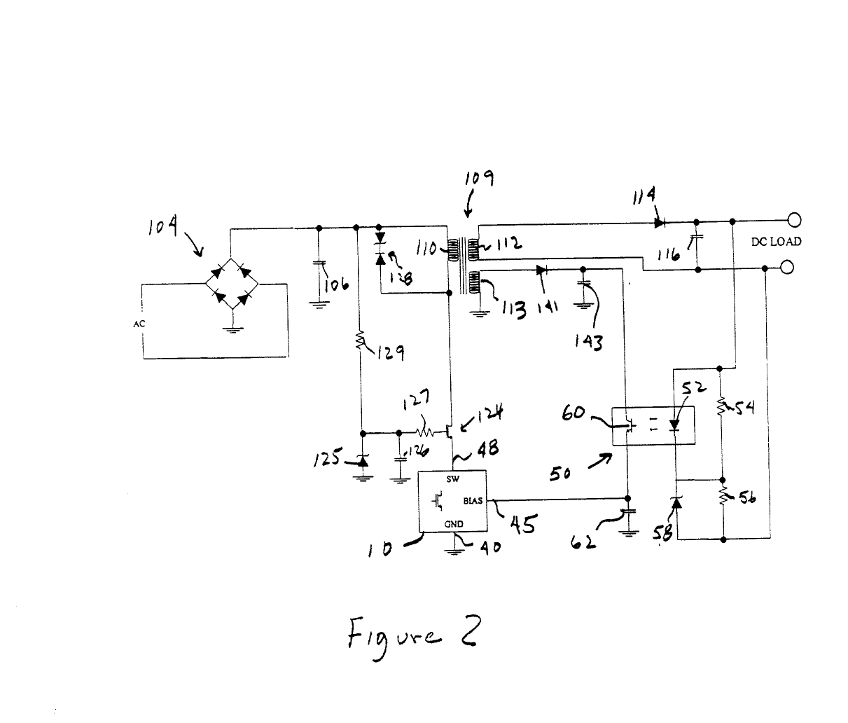

As shown in the controller block diagram of FIG. 3, the primary side PWM controller IC 10 includes in series with the external high voltage switching transistor 124 a current-carrying low voltage switching transistor 28 controlled by width-modulated pulses and a low value current-overload-sensing resistor 128 to primary side ground.

The primary side controller IC 10 receives control information from at least two sources. In the FIG. 1 example, one source of feedback information, such as an error voltage representing output voltage to the load is obtained from the third bias winding 113 of the transformer 109. A rectifier 141 and smoothing capacitor 143 provide secondary-side feedback, and also provide operating power to the PWM controller 10 at a terminal FB/BIAS 45. Alternatively, a sense resistor and a voltage reference, with or without an amplifier may be used to develop the output voltage/current feedback signal.

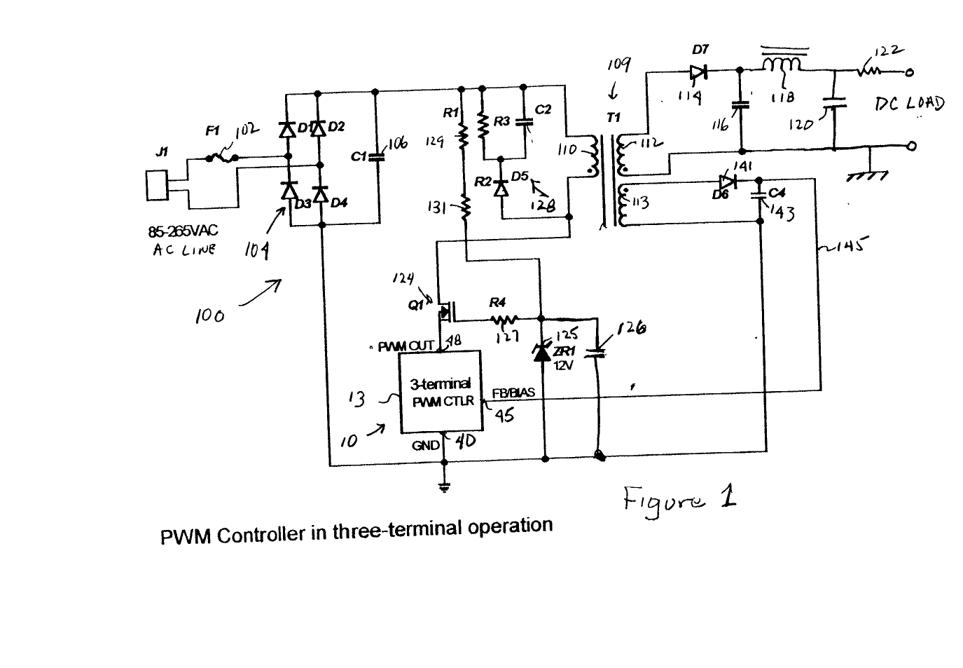

An isolation device may be employed to provide isolation across a high voltage (e.g. three kilovolt) isolation barrier separating the primary side from the secondary side of power supply 100, for example. In a configuration shown in FIG. 2, an opto-isolator 50 serves as the isolation device and provides isolation between the secondary (load) side and the primary (off-line) side. The circuit of FIG. 2 has an advantage of directly measuring output voltage provided to the load to create a feedback control signal that is passed across the opto-isolator 50. A light-emitter 52 of opto-isolator 50 is connected to a common node of a series resistor network of resistors 54 and 56 connected from the DC output to secondary side ground. A zener diode 58 establishes a reference operating voltage for light-emitting-element 52. The light level passed by element 52 to a photo-detector element 60 provides a measure of the voltage present at the DC output of power supply 100 feeding an external load. Variations in output voltage relative to reference operating voltage result in changes in light level, and changes in the error signal fed back to the PWM controller IC at node 45. A capacitor 62 connected at bias terminal 45 provides energy storage for chip-startup, explained in connection with FIG. 3. Other elements of the FIG. 2 power supply which are common with the supply 100 of FIG. 1 bear the same reference numerals and are not further described.

In an alternative configuration the primary side PWM controller 10 comprises a CMOS circuit array encapsulated in a multi-pin plastic package, configured for conventional through-hole or surface mounting and electrical connection.

Turning to FIG. 3, the primary side PWM controller IC 10 includes a reference clock generator 14, a state control logic block 16, a start-up and over-voltage fault circuit 18, a pseudo-random minimum period delay generator 20, an analog-to-digital (ADC) converter 24, an output driver 26, the output low voltage switching transistor 28, an output current feedback comparator 30, a current feedback control digital-to-analog converter (DAC) 32, a thermal protection circuit 34 and a trimming circuit for setting certain digital operating parameters within the chip 10 at the factory. Each of these circuit elements will be described in further detail below. External pins of the DIP package 12 most preferably include a ground pin 40, a bias supply voltage pin 45, a secondary side feedback pin 44, a negative voltage pin 46, an output switch gate pin 48, and an enable pin 49. These pins are electrically wired or connected to appropriate bonding pads of the IC 10 during the IC packaging process at the factory.

In the circuit of FIG. 3 the primary side controller IC ground pin 40 is grounded to a primary side ground (which is typically isolated from a secondary side ground to provide desired voltage isolation between off-line input and the output). In the 3-terminal package usage examples provided by FIGS. 1 and 2, the chip supply voltage and the feedback error voltage are presented together at pin 45. An internal resistance network comprising series resistors 36, 38, and 40, extend between bias supply voltage pin 45 and enable pin 49, thereby to isolate the feedback voltage from the supply voltage in the multi-pin configuration. An internal programming link 41 shunts resistor 38 for the 3-terminal configuration, and is removed for the multi-pin package configuration. Likewise, an internal ground connection is made at a common node of the resistors 40 and 41 in the 3-pin package configuration, and is removed in the multi-pin package configuration as part of factory programming.

An input voltage comparator 43 in front of ADC 24 connects directly to feedback pin 44 and to a common node of resistors 38 and 40; and, the comparator 43 compares the feedback voltage to an internally generated reference voltage. The difference becomes the error voltage applied to the ADC 24.

The current in transistor 124 is sensed by comparator 30 at resistor 128, and is limited by the chip to protect transistor 124 from over-current events. Three-terminal package implementations of the present invention are desirably adapted for and used in low power switching power supply applications where an on-chip output switching FET 28 of IC 10, connected in series with the source electrode of FET 124, is capable of dissipating heat generated during switching events to the external ambient environment.

At startup, no voltage is present at bias winding 113, and the source of FET 124 is at a level just below the gate bias potential. Thus, in order to provide startup energy for the PWM controller 10, the startup circuit 18 causes a FET 19 to conduct and pass energy from the switching terminal 48 to the bias terminal 45 through a resistor 21 and one-way flow diode 23, whereupon the startup energy is stored in the external capacitor 62 (shown in FIG. 2). A zener diode 25 limits the startup voltage to a predetermined limit, such as 6.3 volts. Once voltage appears from winding 11 3, the startup circuit turns off FET 19 and the IC 10 draws its operating current solely from the bias terminal 45. Undervoltage and overvoltage comparators and logic are included in the circuit 18 to start and stop the startup circuit during operation of the power supply 100. Reference is made to commonly assigned, copending U.S. patent application Ser. No. ______, (Docket No. MP1728-US1) filed on the same date as this application and entitled: “Three-Terminal, Low Voltage Pulse Width Modulation Controller IC” for further details concerning the startup circuit 18 and related startup circuitry of IC 10.

In accordance with aspects of the present invention by simply selectively connecting output pads of the IC chip 10 to connection pins, the primary side controller IC may be configured and used either as a three-pin device or as a four, five or more pin device. This pin/package configuration is carried out at the factory when the IC 10 is encapsulated within the selected package and when its leads are electrically connected to bonding terminal pads of the IC chip and the particular chip is suitably programmed for its particular application/desired characteristics Most preferably, the PWM controller IC 10 is formed as a single chip having generally rectangular dimensions with about a two-to-one aspect ratio (e.g. 200 by 250 microns). By using a standard 0.8 micron line width CMOS fabrication process, an area of approximately 2.26 mm² (3500 mils²) is occupied with integrated circuitry, connection pads, and the like.

Logic Circuit 16

In accordance with principles of the present invention, all of the functions needed to provide pulse width modulation control are carried out in a low voltage CMOS logic chip. One advantage of employing CMOS logic is that the resultant circuit has very high power supply rejection.

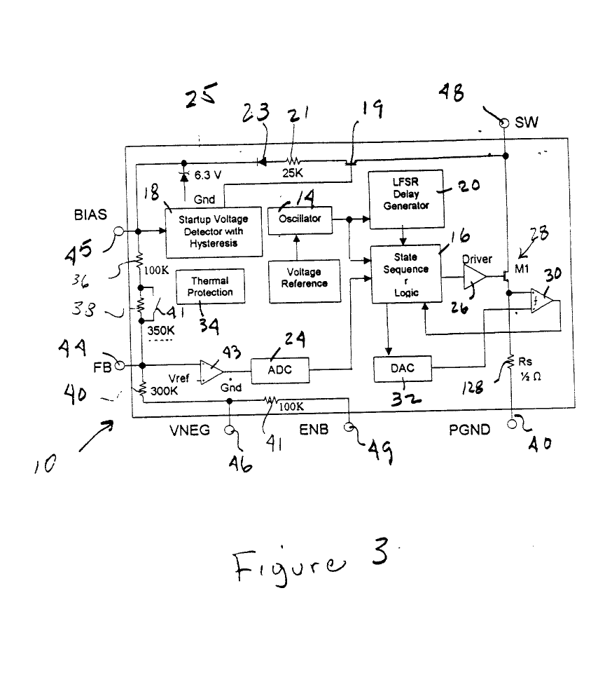

One example of a suitable logic array for realizing a PWM logic controller IC embodied in low-voltage CMOS is shown in FIGS. 4A and 4B. On-chip master timing is implemented by a 7-bit counter 160 clocked at a reference clock frequency, e.g. 120 ns, supplied by the reference clock generator 14. The logic circuit 16 generates a control pulse interval of modulated duration at a nominal frequency of 130 kHz, for example, and synchronously controls all of the timing within the PWM controller IC 10. The timing generator counter 160 starts counting clock pulses at zero and counts up to a last count reached during a PWM control pulse interval. In the presently preferred example, the last count reached in any given interval lies within a range between 64 and 127 counts. Then, the counter 160 resets and the up-counting cycle is repeated continuously during controller operation. Each count value during a count interval is put out over a seven-bit bus 162.

In order to provide controlled frequency dither the pseudo-random period generator 20 incorporates an eight-bit linear feedback shift register (LFSR) 168. When a dither control is asserted as part of programming at the factory, the LFSR 168 generates and puts out five-bit pseudo-random numbers (0-63) in a pattern that repeats every 255 counts. The word pattern looks all “mixed up” random-like or pseudo-random. Each possible 8-bit number (excluding zero) is used only once during each pattern.

Each five-bit number put out by the LFSR 168 is summed with a minimum value of 64 at a summing node 170 and the resultant pseudo-random sum (lying in a range including 64 and 127) is applied as one input to an equivalence circuit 164. The equivalence circuit 164 compares the count put out by the seven-bit counter 160 with the current pseudo-random sum. When equivalence is detected, a clear logic level is asserted on a path 166 which clears the seven-bit counter 160 and causes the next counting period to commence. It also clocks the LFSR 168 which then asserts a next pseudo-random number to summing circuit 170. In this manner the value of last count reached by counter 160 is at least 64 and it varies up to 127 in a pseudo-random fashion. A count interval of 64 represents a highest dither frequency while a count interval of 127 represents a lowest dither frequency in this example. The master clock period variation or “jitter” is provided in a digitally controlled manner in order to lower electromagnetic interference by jittering the PWM switching interval period of the power supply and therefore spreading or smearing the potential interference over a very wide spectrum.

The seven-bit master count on the bus 162 is sent into a count zero comparator 174, a count 63 comparator 176, a blanking comparator 178 controlling a blanking latch 180, a minimum duty cycle comparator 182 controlling a minimum duty cycle latch 184, a maximum duty comparator 186, an ADC comparator 188 and a soft-start comparator 190. The ADC comparator 188 feeds into an AND gate 192 which is enabled by a voltage mode control VMODE and enters an OR gate 196. (During current mode control operation, this function is disabled.) The maximum duty comparator 186 and the soft-start comparator 190 also feed into the OR gate 196. An output of OR gate 196 sets a maximum duty latch 198.

The count zero comparator 174 puts out a control COUNTZERO when the value on the master bus 162 is zero. The count 63 comparator 176 puts out a control COUNT63 when the value on the master bus reaches the count of 63 (which it will reach in each cycle irrespective of the dithered last value). The blanking comparator 178 compares the master bus count value with a blanking value and sets the blanking latch 180 at equivalence. The blanking value is provided to blank a very short duration high current spike that is typically present at the beginning of each switching interval of power supply 100 due to parasitics associated with the primary side circuit, so that nuisance trips are prevented. The minimum duty cycle comparator compares the master bus count value with a minimum duty cycle value and sets the minimum duty cycle latch 184 at equivalence. Once set, the blanking latch 180 asserts a control BLANKOK, the minimum duty cycle latch 184 asserts a control MINDUTYOK, and the maximum duty cycle latch 198 asserts a control MAXDUTYOK, for the duration of the current count interval. When COUNTZERO becomes asserted at the beginning of the next master count interval, latches 180, 184 and 198 are cleared.

The soft-start circuitry 18 includes a divide-by-16 counter 200 which is clocked at the PWM pulse reference rate by the clear value on the path 166 and which in turn clocks a six-bit counter 202. The six-bit counter puts out a sequence of successively increasing values to the soft-start comparator 190 thereby successively increasing the MAXDUTYOK interval. The six-bit counter is cleared by an enable-blanking control ENABLEB.

Turning to FIG. 4B, the MINDUTYOK and the MAXDUTYOK controls are logically ANDed by AND gate 204 to produce a combined control value on path 205. A current limit control ILIMIT is logically ANDed with the BLANKOK control by AND gate 206 to produce a second combined control on path 207. Combined controls on paths 205 and 207 are ORed by OR gate 208 and a composite output thereof is used to reset a maximum period latch 210. The maximum period latch 210 is set at the beginning of each count interval by the COUNTZERO control and has an output which remains true until the latch 210 is reset. A comparator 212 asserts a true output so long as the ADC value is not zero. An AND gate 214 passes a true logic level representing the ADC count reached during each master interval until the latch 210 is reset, thereby determining the present pulse width applied at the gate node 150.

The current limit threshold DAC 32 is preferably a 5-bit DAC and has a digital control, IDAC. IDAC is implemented by an OR gate 216 and by a five-bit OR gate array 218. The current limit threshold DAC 32 has two modes, one of which is set at the factory. In voltage control mode the DAC 32 is always set to full scale. This setting provides for over-current protection. In current control mode, the DAC is set to full scale during the minimum duty cycle interval and at the ADC controlled value during the rest of the interval. This mode allows for both current limit protection and current mode control.

Reference Clock Generator 14

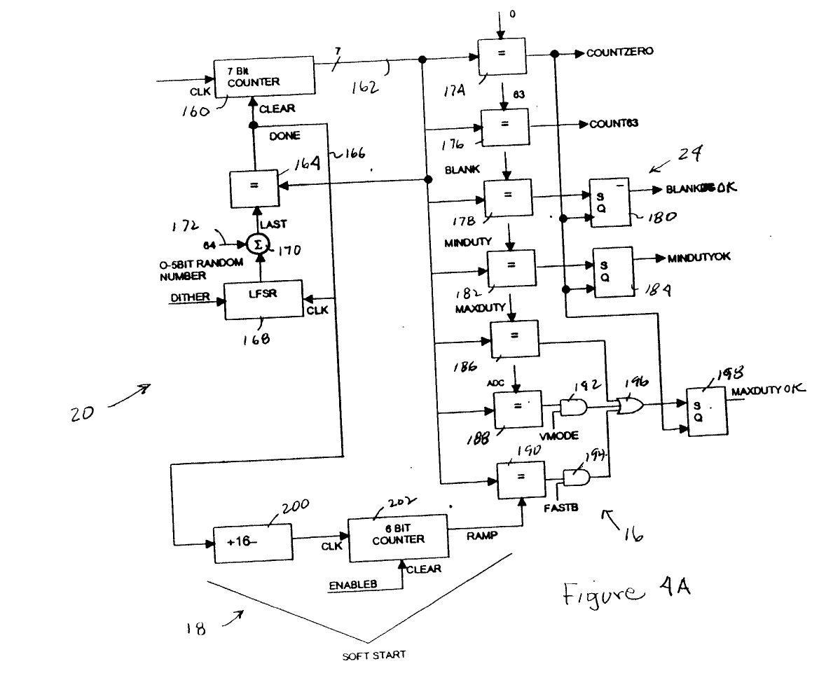

As an alternative to the classic low frequency oscillator within a PLL, the reference clock generator 14 shown in FIG. 3 may follow the switched-capacitor approach shown in the FIG. 5 schematic. This approach yields directly a high frequency clock, having a nominal clock period of 120 ns (a frequency of approximately 8.3 MHz). While a frequency of 8.3 MHz is presently preferred, the oscillator 14 may be configured to operate over a wide frequency range, such as 1-150 MHz. The FIG. 5 approach employs a DC reference current source 220 supplying a constant current in accordance with Iref=Vref/R where R is a fixed internal resistance and where Vref is a reference voltage provided by an on-chip voltage regulator. A switched-capacitor current source 226 switches charge into a transconductance amplifier 222 having an internal feedback capacitance 224 in order to form a simple error integrator. A voltage-controlled-oscillator (VCO) 236 receives a control voltage from the integrator 222 over a path 225 and directly generates the 120 ns period clock.

In addition to providing a reference high frequency clock to the digital logic circuitry 16 and the ADC 30, the VCO 236 provides a clock directly to a divide-by-n counter 238. The divide-by-n counter 238 divides the clock by the divisor n, and the resulting quotient is used to clock a non-overlapping switch phase generator 240 which generates non-overlapping switch phases Phi 1 and Phi 2. The period of these phases is directly controlled by the clock frequency, and the phases provide feedback control to four CMOS switches 228, 230, 232 and 234 connected to cause the capacitor 226 alternatively to charge and discharge, with the charge period being related to the clock period put out by the VCO 236. With a 120 ns clock period, a divisor n of 4 to 8 is presently preferred. The separation of the Phi 1 and Phi 2 switch edges can be small, on the order of nanoseconds.

Operation is as follows: The high frequency clock output from VCO 236 is divided down and drives the switch capacitor current source 226 by way of the non-overlapping switch phase generator 240. If the VCO 236 generates an excessively fast clock, more average current is delivered by the switched capacitor current source 226. The switched capacitor current is compared with the reference current from the reference source 220. The resulting error current is integrated by integrator 222 and provides a negative control voltage to the VCO 236 which decreases the clock frequency and returns the clock loop to equilibrium at the desired clock rate. The reverse situation obtains if the clock is excessively slow. The current signs put out by the integrator 222 to control the VCO 236 are chosen to provide negative feedback. Equilibrium occurs when the switched capacitor current source 226 equals the reference current. The resistor R may also be implemented by a low TC combination of a PTAT and CTAT current sources. The frequency F of the oscillator may be derived with the aid of the following equations and approximations:

$$\hat{i} = Vref \frac{F}{n} C - Vref / R \qquad \hat{i} = Vref ( \frac{F}{n} C - 1 / R ) \approx 0 \qquad ∴ F = \frac{n}{RC}$$

While the reference oscillator 14 may have some inherent frequency jitter, this jitter, if present, is salutary in that it adds to the desirable dither and reduced EMI put out by the PWM controller 10.

Delta-Sigma ADC 30

While Delta-Sigma ADC's are known in the art, use of a synchronous oversampling delta-sigma ADC to sample average error voltage within a CMOS PWM controller provides an elegant, accurate solution to the need for digital quantization of the average error signal. The synchronous delta-sigma ADC 30 comprises an first order modulator followed by an first order sin(x)/x decimation filter. The first order sin(x)/x decimation filter has transmission zeros or “nulls” at the PWM frequency and all of its harmonics. Thus, any order filter provides ideally perfect attenuation of the output ripple. The loop bandwidth of the PWM is much lower than the PWM frequency. As a result, the shaped quantization noise from the ADC is highly attenuated. The effective resolution of the ADC is much higher than the decimation filter output.

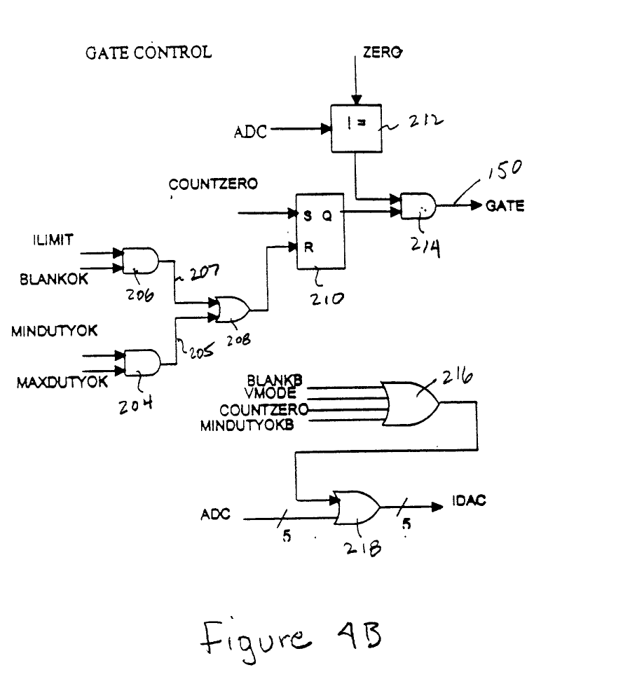

In order to minimize chip die surface area and power dissipation, the preferred embodiment of ADC 30 shown in FIG. 6 is realized as a first order continuous time modulator 246 and a first order decimation filter 248. The modulator 246 includes a transconductance amplifier 250 having an integration capacitor 252 and forming an integrator for integrating the incoming feedback control level from comparator 43. The integrator output is digitized by a voltage comparator 254 clocked by the reference clock. The comparator 254 provides a single-bit digital output feeding into a one-bit DAC 256 clocked by the reference clock. The DAC 256 applies an analog value to an inverting input of the transconductance amplifier 250 where it is added to the input (error or feedback control) voltage level. The first order modulator 246 forms an unstable feedback loop that oscillates with an average duty cycle that is proportional to the input voltage. The instability is caused by the high effective voltage gain of the comparator 254/one bit DAC 256 combination. By using this topology for the feedback, the quantization noise at the comparator output is “shaped” to minimize the low frequency content in accordance with known properties of sigma-delta ADCs of the prior art.

The output of the comparator 254 provides an enable count control for enabling a 6-bit counter 258 to up-count at the reference clock rate during an interval which begins upon assertion of the enable count control and which continues until deassertion of the enable count control. The count reached represents an averaged (filtered) digital representation of the input voltage level. The counter 258 is cleared by the COUNTZERO control, and a new count is accumulated during each PWM cycle. The particular count of clock pulses reached by the counter 258 at the incidence of the COUNT63 control is latched into a register 260 and is supplied as a six-bit ADC output to the logic circuit 16. As used herein the term “decimation” refers to the fact the outputs of counter 258 are used only when COUNT63 is true (this circumstance repeats at a rate equal to the reference clock rate divided by 64). In the presently preferred example, the period of the integrator gm/2πC is approximately 100 kHz with each count interval equaling the master clock period of approximately 120 ns. By using an ADC 30 with an oversampling delta-sigma modulator and a synchronous decimation filter, the average feedback voltage present at the feedback input node 48 is correctly computed for each PWM cycle.

Frequency Jitter

As shown in FIG. 4A, the logic circuit 16 includes a LFSR 168 having a length of 8-bits. The particular length of LFSR 168 controls the low frequency content of the jitter. The LFSR 168 is clocked at the PWM frequency. As noted above, period-dithering reduces the amplitude of the peaks of switching frequency harmonics in the frequency domain by spreading the energy across nearby frequencies. To analyze the relative effect of this dithering process, the original (non-dithered) and dithered PWM signals are filtered by a 9 kHz bandpass filter centered at the fundamental switching frequency. This provides a desired bandwidth at an input of a spectrum analyzer used for making EMI measurements.

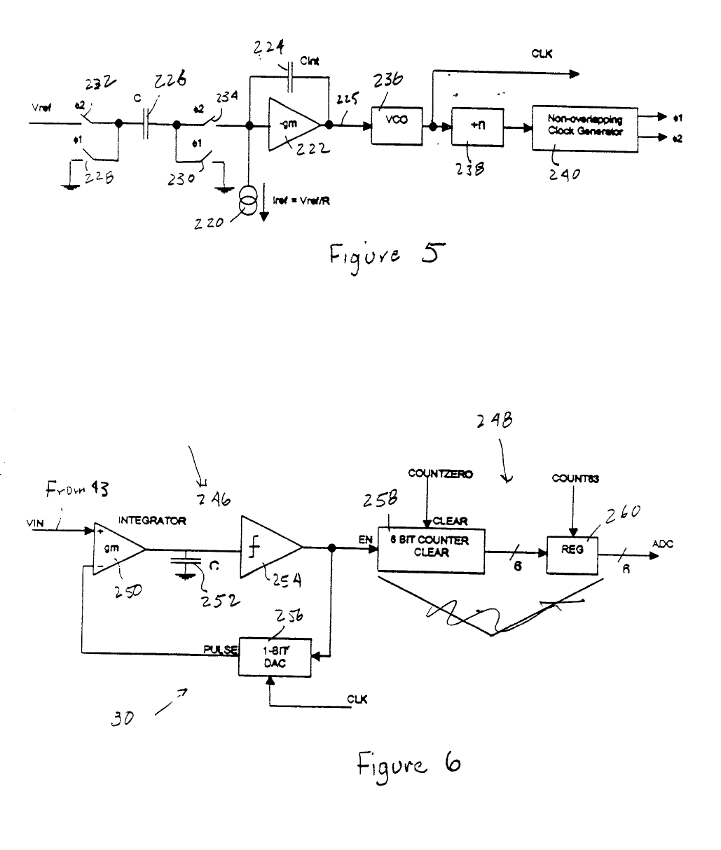

FIG. 7 represents a non-dithered signal depicting current in switching transformer 108 operating with a switching frequency of 130 kHz and a constant 40% duty cycle.

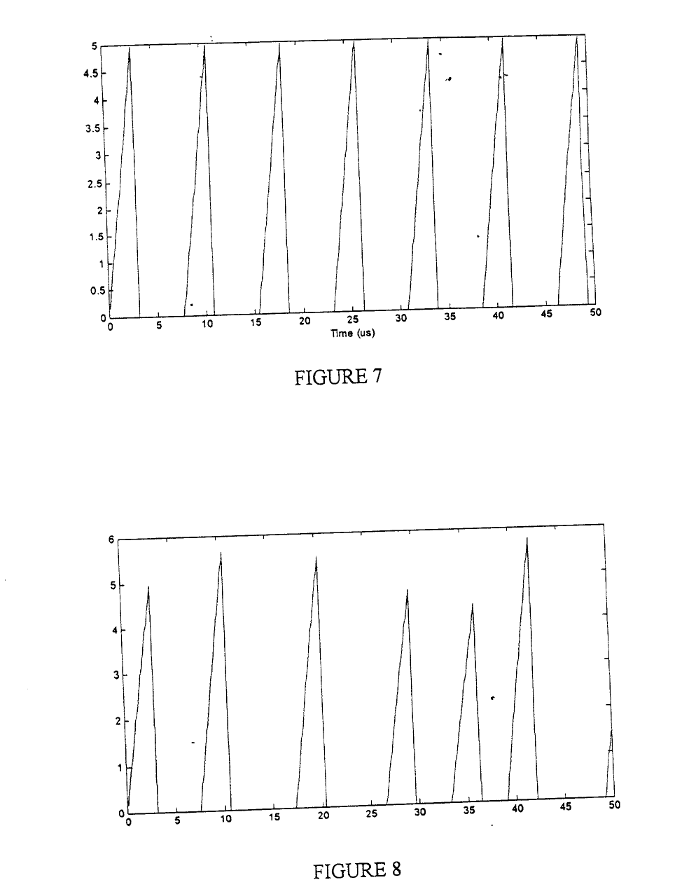

FIG. 8 represents a typical dithered signal at a frequency about 130 kHz. The dithered switching signal was normalized such that it represents the same average current as the non-dithered signal of FIG. 7.

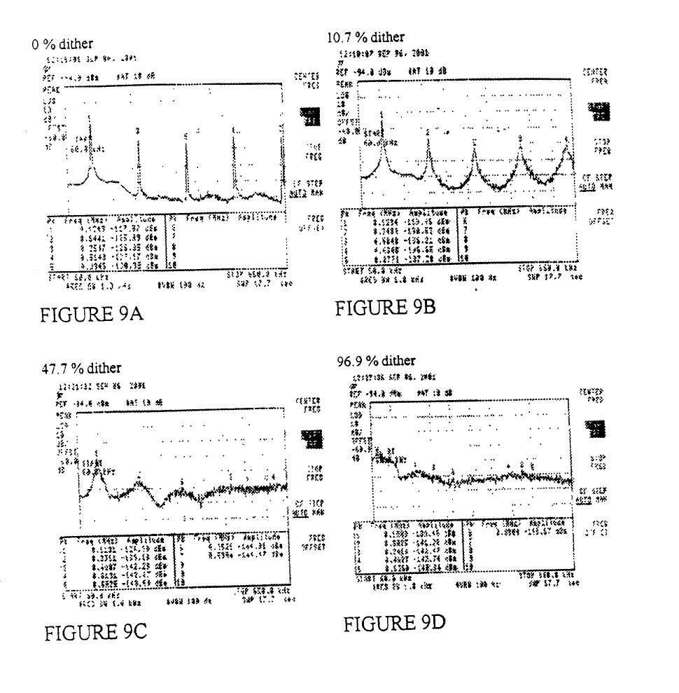

FIGS. 9A, 9B, 9C and 9D represent measured frequency spectra of the primary side PWM controller 10 depicted in FIG. 1 using an 8 bit LFSR 168 with five taps set to generate the period variations. The measurements were taken with a 500 mA load and with a 1 kHz bandwidth set into the spectrum analyzer. FIG. 9A depicts a spectrum with zero dither. FIG. 9B depicts a spectrum with 10.7% dither, and shows some reduction of peak amplitude of harmonics of the switching frequency. FIG. 9C depicts a spectrum resulting from 47.7% dither, showing considerable reduction in spectral switching peaks over a sampling interval. FIG. 9D depicts a spectrum resulting from 96.9% dither, showing virtually no spectral switching peaks but an elevated general noise level across the spectrum being depicted. Of the four examples presented in FIGS. 9A, 9B, 9C and 9D, the dithering level of 96.9% shown in FIG. 9D represents the greatest level of resultant EMI reduction.

Thus, it will be appreciated that by using a CMOS logic implementation for the PWM controller 10, precise and robust jitter may be added in a controlled manner, unlike the random approaches taken in the prior art. The digital jitter imposed upon the PWM switching signal by the LSFR 168 is simple to measure and test.

Having thus described preferred embodiments of the invention, it will now be appreciated that the objects of the invention have been fully achieved, and it will be understood by those skilled in the art that many changes in construction and widely differing embodiments and applications of the invention will suggest themselves without departing from the spirit and scope of the invention.

For example, the reference oscillator may be employed in many digital applications beyond PWM control, such as microprocessor clock control, for example. The delta-sigma ADC, clocked by the reference oscillator, may also be employed in vastly varying applications and environments. The PWM controller, while illustrated in association with switching off-line power supplies and DC-to-DC converters may be employed in other applications such as motor speed control and regulation. Therefore, the disclosures and descriptions herein are purely illustrative and are not intended to be in any sense limiting.

What is claimed is:

1. A digital pulse width modulation (PWM) controller embodied in a unitary monolithic complementary metal oxide semiconductor (CMOS) integrated circuit (IC) and comprising:
(a) an input node for receiving a feedback control value related to an output parameter of an electrical circuit controlled by the digital PWM controller,
(b) a digital output switch connected to an output node for providing digital width-modulated control pulses at a control pulse rate to control duty cycle of the power circuit, the digital width-modulated control pulses being width-modulated in relation to the feedback control value,
(c) a digital reference clock generator for generating a reference clock at a reference clock rate much higher than the control pulse rate,
(d) an oversampling analog-to-digital converter for sampling the first feedback control value at the reference clock rate and for converting and filtering the first feedback control value at the input into digital feedback words at the control pulse rate, and,
(e) digital control logic clocked at the reference clock rate for establishing a minimum control pulse interval, a maximum control pulse interval, and a data acquisition interval; for synchronizing and controlling the oversampling analog-to-digital converter at the control pulse rate and for generating and applying the digital width-modulated control pulses to the digital output switch at the control pulse rate.

2. The CMOS digital PWM controller set forth in claim 1 wherein the digital reference clock generator generates the reference clock at a rate in a range between approximately 10 times and 100 times the control pulse rate.

3. The CMOS digital PWM controller set forth in claim 1 wherein the digital control logic includes a digital jitter circuit for adding digitally generated jitter to the control pulse rate to reduce electromagnetic interference.

4. The CMOS digital PWM controller set forth in claim 3 wherein the digital jitter circuit includes a linear feedback shift register clocked at the reference clock rate.

5. The CMOS digital PWM controller set forth in claim 4 wherein the linear feedback shift register is configurable to generate a pseudo-random jitter count having a value which when added to the a count corresponding approximately to the minimum control pulse interval results in a sum of counts representing an interval within the minimum control pulse interval and the maximum control pulse interval.

6. The CMOS digital PWM controller set forth in claim 1 wherein the first oversampling ADC comprises a delta-sigma analog-to-digital converter (ADC).

7. The CMOS digital PWM controller set forth in claim 6 wherein the synchronous delta-sigma ADC comprises a digital n^{th} order modulator followed by a digital m^{th} order sinx/x decimation filter.

8. The CMOS digital PWM controller set forth in claim 7 wherein the synchronous delta-sigma ADC comprises a digital first order modulator followed by a digital first order sinx/x decimation filter.

9. The CMOS digital PWM controller set forth in claim 1 further comprising second parameter sensing circuit means for sensing a second operating parameter of the power circuit; and, wherein the digital control logic receives and uses the second operating parameter to control generation of the digital width-modulated control pulses applied to the digital output switch at the control pulse rate.

10. The CMOS digital PWM controller set forth in claim 9 wherein the second parameter sensing circuit means includes an overcurrent comparator circuit for sensing overcurrent of an external switching transistor of the electrical circuit controlled by the digital output switch.

11. The CMOS digital PWM controller set forth in claim 9 wherein the second parameter sensing circuit includes a digital-to-analog converter (DAC) circuit controlled by digital control logic for establishing a reference current level at the overcurrent comparator circuit.

12. The CMOS digital PWM controller set forth in claim 10 further comprising a low resistance overcurrent sensing resistor element connected between a ground node connection of the controller and the digital output switch connected to the output node, and wherein the overcurrent comparator circuit is connected to the overcurrent sensing resistor element.

13. The CMOS digital PWM controller set forth in claim 1 wherein digital reference clock generator generates a reference clock at a reference clock rate much higher than the control pulse rate without requiring any frequency-setting circuit elements external to the IC.

14. The CMOS digital PWM controller set forth in claim 13 wherein the digital reference clock generator comprises within a circuit loop:
(i) a switched capacitor current source having a characteristic capacitance C,
(ii) an error integrator including a dc reference current source having a characteristic current of a reference voltage (Vref) divided by a characteristic resistance (R),
(iii) a high frequency voltage controlled oscillator,
(iv) a divide-by-n counter, and,
(v) a non-overlapping clock generator for controlling the switch capacitor current source,
such that an output frequency F of the reference clock is approximately equal to n/RC.

15. The CMOS digital PWM controller set forth in claim 1 wherein the digital state control logic includes soft start logic for starting up the digital PWM controller during an initial IC power on interval.

16. The CMOS digital PWM controller set forth in claim 1 wherein the digital control logic comprises:
(a) a multi-bit digital counter clocked at the reference clock rate for generating each control pulse interval,
(b) a period control pulse interval circuit for comparing a count reached by the multi-bit digital counter with an interval value greater than n determined to represent a present control pulse interval, and for clearing the multi-bit digital counter at equivalence,
(c) a count-zero comparator for putting out a COUNTZERO value to clear the first ADC when the multi-bit digital counter is cleared, and
(d) a count n comparator for putting out a COUNTN value to latch a count reached by the ADC when the multi-bit digital counter reaches a count of n.

17. The CMOS digital PWM controller set forth in claim 16 wherein the period control pulse interval circuit includes a linear feedback shift register clocked at a rate equal to a repetition rate of the present control pulse interval for generating a pseudo-random PWM period.

18. The CMOS digital PWM controller set forth in claim 16 wherein the digital control logic further comprises a minimum duty comparator for comparing a count reached by the multi-bit digital counter with a predetermined minimum duty interval value and a minimum duty latch set true upon equivalence thereof for providing a MINDUTYOK control; a maximum duty comparator for comparing a count reached by the multi-bit digital counter with a predetermined maximum duty interval value and a maximum duty latch set true upon equivalence thereof for providing a MAXDUTYOK control; the minimum duty latch and the maximum duty latch being reset by the COUNTZERO value; a duty interval AND gate set true when MINDUTYOK and MAXDUTY controls are true; a PWM interval latch set by the COUNTZERO value and reset when the AND gate is set true; and a PWM AND gate for passing the ADC value for so long as the PWM interval latch remains set.

19. The CMOS digital PWM controller set forth in claim 1 wherein the digital state control logic includes digital logic elements for the control of controlling PWM duty cycle within a range lying within a minimum duty cycle limit, and a maximum duty cycle limit.

20. The CMOS digital PWM controller set forth in claim 19 further including a blanking comparator for comparing a count reached by the multi-bit digital counter with a predetermined blanking interval value, and a blanking latch set by the blanking comparator and cleared by the COUNTZERO control for providing a BLANKOK control.

21. The CMOS digital PWM controller set forth in claim 19 wherein the digital logic elements include elements responsive to the BLANKOK control for establishing PWM duty cycle range in relation to a current limit.

22. The CMOS digital PWM controller set forth in claim 19 wherein the digital logic elements also establish PWM duty cycle range in relation to a soft start sequence.

23. The CMOS digital PWM controller set forth in claim 1 wherein the IC is factory-configured, packaged and connected as one of three-terminal electronic device configuration and multi-terminal electronic device configuration.

24. The CMOS digital PWM controller set forth in claim 1 wherein the electrical circuit comprises a switching power supply.

25. The CMOS digital PWM controller set forth in claim 24 further comprising a startup circuit for controlling a path for conducting voltage present at the output node to a bias node during an initial power up sequence and for disconnecting the path after bias voltage is determined to be present at the bias node.

26. A digital pulse width modulation (PWM) controller chip having
(1) a clock generator for directly generating a sampling clock at a frequency higher than a control pulse rate without requiring a phase locked loop,
(2) an oversampling analog-to-digital converter clocked by the sampling clock for converting error signals into filtered digital values,
(3) an output for controlling duty cycle of an electrical device in accordance with width-modulated digital control pulses supplied at the control pulse rate, and,
(4) digital control logic for receiving the digital values and for generating the width-modulated digital control pulses in relation to the digital values.

27. The digital PWM controller chip set forth in claim 26 wherein the digital control logic includes:
(a) a multi-bit digital counter clocked at the reference clock rate for generating control pulse intervals,
(b) a period control pulse interval circuit for comparing a count reached by the multi-bit digital counter with an interval value, and for clearing the multi-bit digital counter at equivalence,
(c) a count-zero comparator for putting out a COUNTZERO value to clear the ADC when the multi-bit digital counter is cleared, and
(d) a comparator for putting out a COUNTN value to latch a value held by the ADC when the multi-bit digital counter reaches the interval value.

28. The digital PWM controller chip set forth in claim 27 wherein the digital control logic includes a minimum duty comparator for comparing a count reached by the multi-bit digital counter with a predetermined minimum duty interval value and a minimum duty latch set true upon equivalence thereof for providing a minimum duty control;
a maximum duty comparator for comparing a count reached by the multi-bit digital counter with a predetermined maximum duty interval value and a maximum duty latch set true upon equivalence thereof for providing a maximum duty control; the minimum duty latch and the maximum duty latch being reset by the COUNTZERO value;
a duty interval AND gate set true when the minimum duty and maximum duty controls are true;
a PWM interval latch set by the COUNTZERO value and reset when the AND gate is set true; and,
a PWM AND gate for passing the ADC value for so long as the PWM interval latch remains set.

29. The digital PWM controller chip set forth in claim 27 further comprising a linear feedback shift register clocked at a rate equal to a repetition rate of the present control pulse interval for generating and applying a pseudo-random sequence to the period control pulse interval circuit to aid generating a pseudo-random PWM period.

30. The digital PWM controller chip set forth in claim 26 wherein the clock generator for directly generating the sampling clock at a frequency higher than a control pulse rate without requiring a phase locked loop includes within a circuit loop:
(i) a switched capacitor current source having a characteristic capacitance C,
(ii) an error integrator including a dc reference current source having a characteristic current of a reference voltage (Vref) divided by a characteristic resistance (R),
(iii) a high frequency voltage controlled oscillator,
(iv) a divide-by-n counter, and,
(v) a non-overlapping clock generator for controlling the switch capacitor current source,
such that an output frequency F of the reference clock is approximately equal to n/RC.

31. The digital PWM controller chip set forth in claim 26 wherein the oversampling analog-to-digital converter (ADC) comprises a synchronous delta-sigmna ADC including a digital n^{th} order modulator followed by a digital ^{th} order sinx/x decimation filter.

32. The digital PWM controller chip set forth in claim 31 wherein the synchronous delta-sigma ADC comprises a digital first order modulator followed by a digital first order sinx/x decimation filter.

33. The digital PWM controller chip set forth in claim 26 wherein the chip is formed as a low voltage complementary metal oxide silicon integrated circuit.

34. A clock generator embodied as an integrated circuit (IC) without any frequency determining elements external to the IC for directly generating a high frequency and without requiring a phase locked loop comprising within a circuit loop:
(i) a switched capacitor current source having a characteristic capacitance C,
(ii) an error integrator including a dc reference current source having a characteristic current of a reference voltage (Vref) divided by a characteristic resistance (R),
(iii) a high frequency voltage controlled oscillator,
(iv) a divide-by-n counter, and,
(v) a non-overlapping clock generator for controlling the switch capacitor current source,
such that an output frequency F of the reference clock is approximately equal to n/RC.

35. The clock generator set forth in claim 32 wherein the high frequency voltage oscillator generates a high frequency in a range bounded by one and 150 MHz.

36. An electronic circuit embodied within a complementary metal oxide silicon integrated circuit chip having an input for sampling a signal at an input and for providing digital output values at a data output rate, the circuit including:
(a) a clock generator for directly generating a sampling clock at a frequency much higher than the data output rate without requiring a phase locked loop; and,
(b) an oversampling analog-to-digital converter clocked by the sampling clock for converting the signal into filtered digital values at the data output rate.

37. The electronic circuit set forth in claim 36 wherein the clock generator comprises:
(i) a switched capacitor current source having a characteristic capacitance C,
(ii) an error integrator including a dc reference current source having a characteristic current of a reference voltage (Vref) divided by a characteristic resistance (R),
(iii) a high frequency voltage controlled oscillator
(iv) a divide-by-n counter, and,
(v) a non-overlapping clock generator for controlling the switch capacitor current source,
such that an output frequency F of the reference clock is approximately equal to n/RC.

38. The electronic circuit set forth in claim 36 wherein the oversampling analog-to-digital converter (ADC) comprises a synchronous delta-sigma ADC including a digital n^{th} order modulator followed by a digital m^{th} order sinx/x decimation filter.

39. The digital PWM controller chip set forth in claim 37 wherein the synchronous delta-sigma ADC comprises a digital first order modulator followed by a digital first order sinx/x decimation filter.

40. A digital pulse width modulation (PWM) controller integrated circuit chip including:
(a) a clock generator for generating a sampling clock,
(b) an analog-to-digital converter clocked by the sampling clock for converting error signals into filtered digital values,
(c) an output for controlling duty cycle of an electrical device in accordance with width-modulated digital control pulses, and,
(d) digital control logic for receiving the digital values and for generating the width-modulated digital control pulses in relation to the digital values, the digital control logic including a digital jitter circuit for adding digitally generated jitter to the control pulses to reduce electromagnetic interference.

41. The digital PWM controller set forth in claim 40 wherein the digital jitter circuit includes a linear feedback shift register for generating a repeating pseudo-random digital sequence, and a digital combining circuit for combining each value of the pseudo-random digital sequence with sequential ones of the digital values to provide pseudo-randomized control pulses.
